(19) United States
(12) Patent Application Publication
(10) Pub. No.: US 2008/0123443 A1
(43) Pub. Date: May 29, 2008

(54) Semiconductor memory device and method for driving the same

(75) Inventor: Se-Kyoung Heo, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/819,569

(22) Filed: Jun. 28, 2007

(30) Foreign Application Priority Data
Nov. 24, 2006 (KR) 2006-0116858

(51) Int. Cl. G11C 7/00

(52) U.S. Cl. 365/193

(57) ABSTRACT

A semiconductor memory device includes: an internal command signal generator for receiving an external command signal and a command strobe signal from a chipset to generate an internal command signal by decoding the external command signal in response to the command strobe signal; and a plurality of operation circuits for performing an internal operation of the semiconductor memory device based on the internal command signal.

### CROSS-REFERENCE TO RELATED APPLICATIONS

The present invention claims priority of Korean patent application number 10-2006-0116858, filed on Nov. 24, 2006, which is incorporated by reference in its entirety.

### BACKGROUND OF THE INVENTION

The present invention relates to a semiconductor memory device, and more particularly, to a semiconductor memory device, which can receive an external command signal from a chipset at high stability and reliability, and a method for driving the same.

In semiconductor memory devices, a setup time and a hold time are defined for inputs of external signals such as external address signals and external command signals, or external data. The external signals can be stably latched when they are input before a predetermined time from an input of an external clock signal. In addition, the external signals can be correctly detected when their levels are maintained for a predetermined time after the input of the external clock signal. At this point, the time interval during which the external signals must be stabilized before the input of the external clock signal is referred to as the setup time, and the time interval during which the external signals must be maintained after the input of the external clock signal is referred to as the hold time.

Meanwhile, the external signals are transferred from a chipset to a semiconductor memory device, e.g., a dynamic random access memory (DRAM), in synchronization with an external clock signal.

FIG. 1 is a block diagram illustrating a transfer path of an external command signal between a chipset and a DRAM in a conventional system.

Referring to FIG. 1, a transfer path CMDPATH of an external command signal in a conventional system is directed from a chipset to a DRAM. A transfer path CLKPATH1 of a clock signal is directed from a clock generator to the DRAM, and another transfer path CLKPATH2 of the clock signal is directed from the clock generator to the chipset. The chipset and the DRAM operate in synchronization with the clock signal.

However, it can be seen from FIG. 1 that the transfer path CLKPATH1 of the clock signal and the transfer path CMDPATH of the external command signal are different from each other.

The difference between the transfer paths CLKPATH1 and CMDPATH may degrade the reliability and stability of the DRAM operating at high speed.

In other words, when an internal command signal is latched in synchronization with the clock signal that is delayed by a loading difference from the external command signal, the above-described degradation is caused because the decoded external command signal is latched incorrectly due to an insufficient setup time.

As described above, compared with the case where the decoded external command signal is normally latched in synchronization with the clock signal, the clock signal is delayed because the transfer path CLKPATH1 of the clock signal is longer than the transfer path CMDPATH of the external command signal. On the other hand, the reliability and stability of the DRAM operating at high speed are degraded when the transfer path CMDPATH of the external command signal is longer than the transfer path CLKPATH1 of the clock signal.

### SUMMARY OF THE INVENTION

Embodiments of the present invention are directed at providing a semiconductor memory device, which can receive an external command signal from a chipset at high reliability and stability, and a method for driving the same.

Embodiments of the present invention are also directed at providing a semiconductor memory device, which can receive an external command signal in synchronization with a command strobe signal transferred from a chipset, and a method for driving the same.

In accordance with an aspect of the present invention, there is provided a semiconductor memory device, including: a plurality of command pins for receiving a plurality of command signals from a chipset; and a command strobe pin for receiving a command strobe signal from the chipset.

In accordance with another aspect of the present invention, there is provided a semiconductor memory device, including: an internal command signal generator for receiving an external command signal and a command strobe signal from a chipset to generate an internal command signal by decoding the external command signal in response to the command strobe signal; and a plurality of operation circuits for performing an internal operation of the semiconductor memory device based on the internal command signal.

In accordance with further another aspect of the present invention, there is provided a method for driving a semiconductor memory device, including: receiving an external command signal and a command strobe signal from a chipset to generate an internal command signal in response to the command strobe signal; and performing an internal operation of the semiconductor memory device based on the internal command signal.

### BRIEF DESCRIPTION OF THE DRAWINGS

FIG. 1 is a block diagram illustrating a transfer path of an external command signal in a conventional system;

FIG. 2 illustrates a transfer path of a write data and a timing diagram of the write data and a data strobe signal;

FIG. 3 is a block diagram illustrating a transfer path of an external command signal in a system in accordance with an embodiment of the present invention;

FIG. 4 is a block diagram of an internal command signal generator of a DRAM shown in FIG. 3;

FIG. 5 is a circuit diagram of a latch unit illustrated

FIG. 6 is a diagram of a DRAM chip having pads for receiving a command strobe signal.

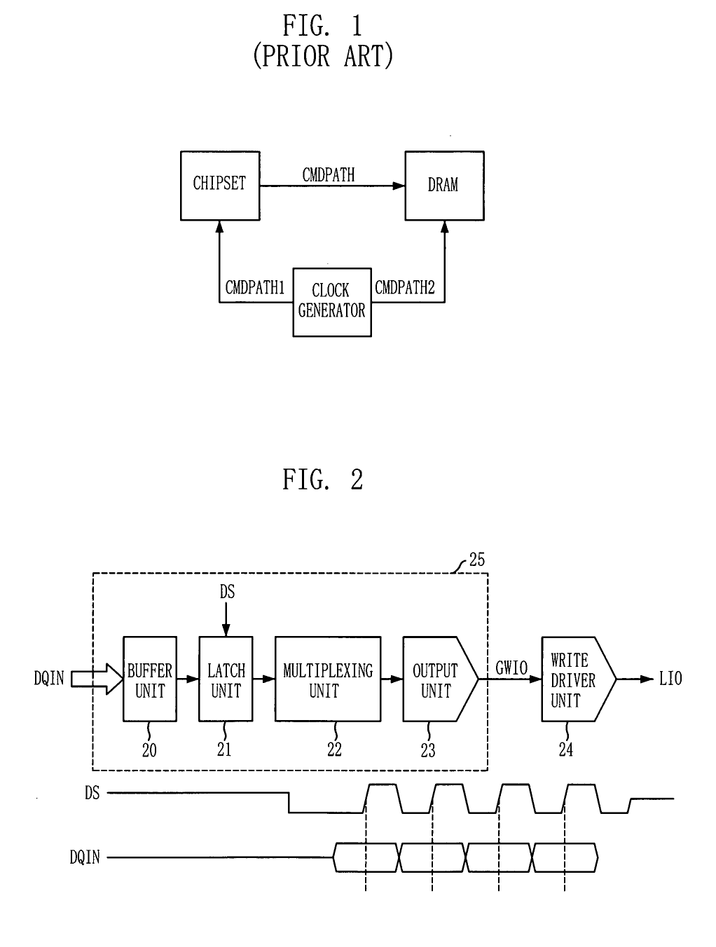

### DESCRIPTION OF SPECIFIC EMBODIMENTS

Hereinafter, a semiconductor memory device for receiving an external command signal from a chipset at high stability and reliability and a method for driving the same in accordance with exemplary embodiments of the present invention will be described in detail with reference to the accompanying drawings.

A dynamic random access memory (DRAM) as a typical semiconductor memory device has been developed in order to provide high integration and high operating speed. In order to increase the operation speed of the semiconductor memory device, synchronous DRAMs (SDRAMs) have been introduced which operate in synchronization with an external clock signal.

The SDRAMs can be classified into a single data rate (SDR) SDRAM and a double data rate (DDR) SDRAM. The SDR SDRAM receives/outputs a single data through a single data pin in synchronization with a rising edge of an external clock signal during one cycle of the external clock signal.

The SDR SDRAM, however, is still insufficient to satisfy the required high-speed operation of systems. Accordingly, the DDR SDRAM was proposed which can process two data during one cycle of the external clock signal.

The DDR SDRAM successively receives/outputs two data through data input/output pins in synchronization with a rising edge and a falling edge of the external clock signal. Therefore, the DDR SDRAM can obtain at least twice the bandwidth of the SDR SDRAM. Consequently, the high-speed operation of the semiconductor memory device can be implemented.

However, a data access scheme of the SDR SDRAM cannot be used in the DDR SDRAM because the DDR SDRAM must receive/output two data during one cycle of the clock signal.

For example, when the clock cycle is 10 ns, the DDR SDRAM must successively process two data within about 6 nsec, excluding the rising time and the falling time (about 0.5×4=2 ns), time necessary to satisfy other specifications, etc. This process is difficult to perform within the DRAM. For this reason, the DRAM receives/outputs data at the rising edge and the falling edge only when it receives/outputs data from/to the outside, and the two data synchronized with one edge of the clock signal are substantially processed in parallel within the DRAM.

Therefore, the DRAM requires a new data access scheme to transfer data to a core region or output data from the core region to the external circuit.

To this end, a data input buffer of the DDR SDRAM prefetches 2-bit data synchronized with the rising edge and the falling edge. The prefetched data are synchronized as even data or odd data at the rising edge and then are transferred to the core region.

However, as an operation frequency of a central processing unit (CPU) becomes higher, the DRAM must be designed to operate at higher speed. To this end, a data input buffer has been proposed which can prefetch 4-bit data.

Meanwhile, a data strobe signal is also inputted from a CPU or a memory controller chipset together with a data signal in order to achieve correct data input/output timing.

FIG. 2 illustrates a transfer path of a write data and a timing diagram of the write data and a data strobe signal.

Referring to FIG. 2, a write data DQIN is transferred to a memory cell through a DQ part 25, a global input/output line GWIO, a write driver unit 24, a local input/output line LIO, and a bit line. The DQ part 25 includes a buffer unit 20, a latch unit 21, a multiplexing unit 22, and an output unit 23.

The buffer unit 20 buffers levels between the external write data DQIN and the internal operation of the DRAM. The latch unit 21 latches the buffered write data DQIN as the data strobe signal DS.

The multiplexing unit 22 matches the latched write data DQIN to a write address signal. The output unit 23 transfers the write data DQIN to the global input/output line GWIO.

It can be seen from FIG. 2 that the write data DQIN is latched in response to the data strobe signal DS.

The present invention applies the data transfer scheme to a command transfer between the DRAM and the chipset. In receiving the external command signal, the DRAM receives the command strobe signal together with the external command signal from the chipset provided outside the DRAM in order to achieve the correct input/output timing of the external command signal.

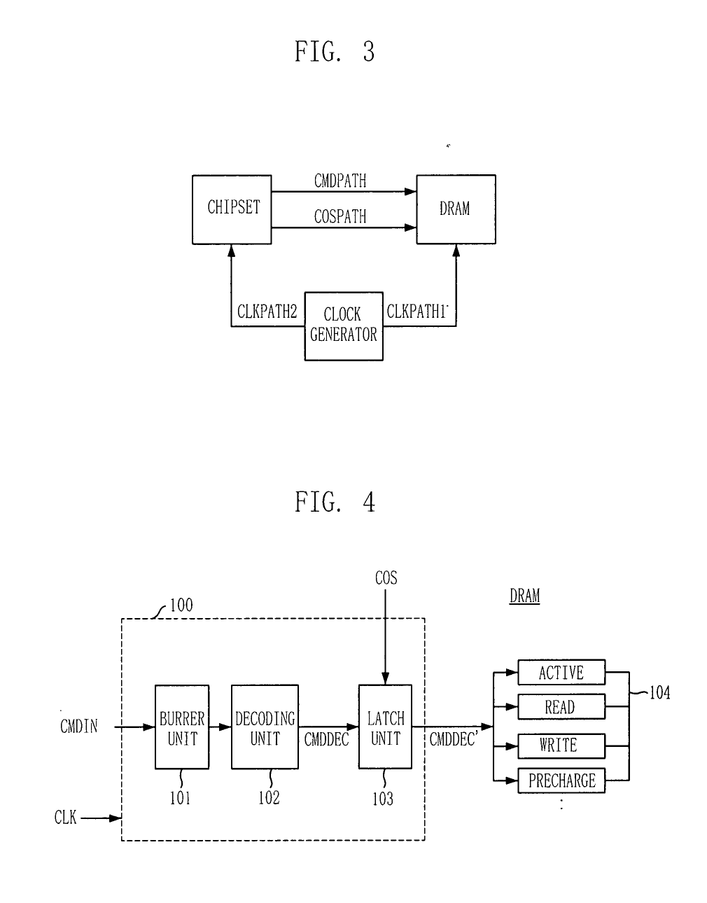

FIG. 3 is a block diagram illustrating a transfer path of an external command signal in a system in accordance with an embodiment of the present invention.

Referring to FIG. 3, a transfer path CMDPATH of an external command signal is directed from a chipset to a DRAM. A transfer path CLKPATH1 of a clock signal is directed from a clock generator to the DRAM, and another transfer path CLKPATH2 of the clock signal is directed from the clock generator to the chipset. The chipset and the DRAM operate in synchronization with the clock signal.

The chipset outputs the external command signal with a command strobe signal. The command strobe signal is generated for a correct input/output timing of the external command signal when the external command signal is transferred between the chipset and the DRAM.

The transfer path CMDPATH of the external command signal and a transfer path COSPATH of the command strobe signal have the same loading. The correct input/output timing of the external command signal in the system can be implemented using the external command signal and the command strobe signal transferred through the same loading.

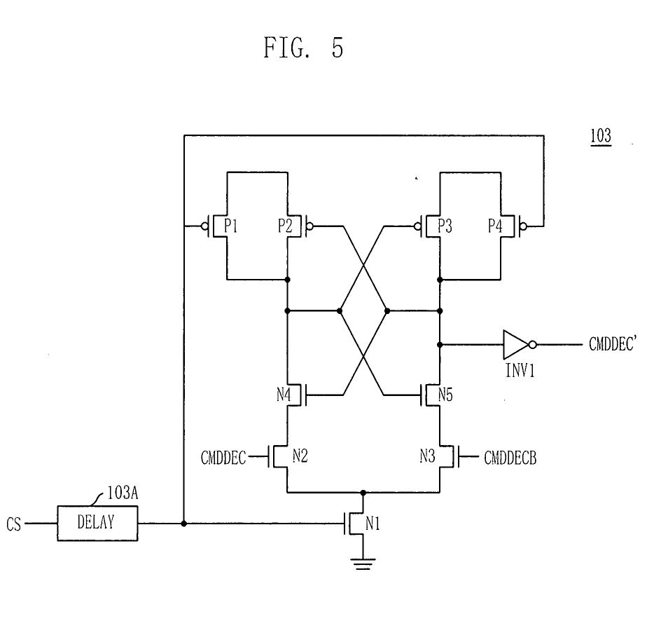

FIG. 4 is a block diagram of an internal command signal generator 100 of the DRAM shown in FIG. 3.

Referring to FIG. 4, the internal command signal generator 100 of the DRAM includes a buffer unit 101, a decoding unit 102, and a latch unit 103. Although not shown, the internal command signal generator 100 further includes a command strobe signal input unit for receiving a command strobe signal COS from the chipset. The command strobe signal COS is an echo signal of the external command signals CMDIN.

More specifically, the buffer unit 101 includes a plurality of command input units for receiving the plurality of external command signals CMDIN from the chipset. The buffer unit 101 buffers levels between the external command signals CMDIN and the internal operation of the DRAM. The external command signals CMDIN include a chip select signal (/CS), a row address strobe signal (/RAS), a column address strobe signal (/CAS), and a write enable signal (/WE). The decoding unit 102 decodes the buffered external command signals CMDIN and outputs a decoded external command signal CMDDEC so as to designate a state of the DRAM according to the contents of the decoded external command signal CMDDEC. The latch unit 103 latches the decoded external command signal CMDDEC to output the internal command signals CMDDEC′ in response to the command strobe signal COS.

As described above, the internal command signals CMDDEC′ output from the internal command signal generator 100 are transferred to active/read/write/precharge circuits 104 according to the contents of the respective command signals CMDIN.

The internal command signal generator 100 receives the external command signals CMDIN in response to the command strobe signal COS. While the conventional internal command signal generator receives the external command signals in response to the external clock signal, the internal command signal generator 100 in accordance with the present invention receives the external command signals CMDIN in response to the command strobe signal COS transferred through the same loading as the external command signals CMDIN.

In this manner, the DRAM in accordance with the present invention can solve the skew problem that is caused between the clock signal and the external command signal because the transfer path CLKPATH1 of the clock signal between the clock generator and the DRAM is different from the transfer path CMDPATH of the external command signal between the chipset and the DRAM.

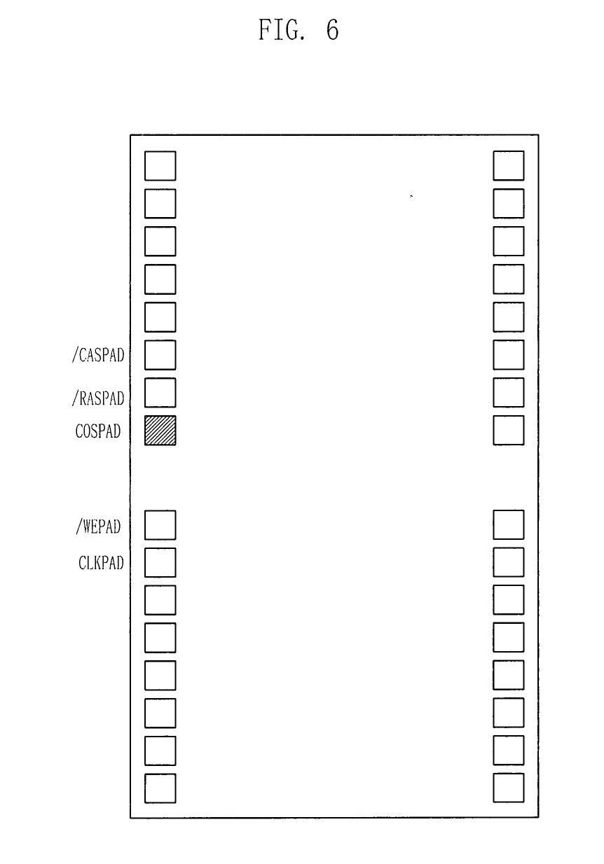

FIG. 5 is a circuit diagram of the latch unit 103 illustrated in FIG. 4.

Referring to FIG. 5, the latch unit 103 includes first to fourth PMOS transistors P1 to P4, first to fifth NMOS transistors N1 to N5, a delay unit 103A, and an inverter INV1.

When the command strobe signal COS is deactivated to a logic low level, the first and fourth PMOS transistors P1 and P4 are turned on and the first NMOS transistor N1 is turned off. As a result, the latch unit 103 does not output the internal command signals CMDDEC.

The case where the command strobe signal COS has the logic low level represents a state where no external command signals CMDIN are applied to the DRAM. On the other hand, the case where the command strobe signal COS has a logic high level represents a state where the external command signals CMDIN are applied to the DRAM.

When the command strobe signal COS changes from the logic low level to the logic high level, the first NMOS transistor N1 is turned on so that the latch unit 103 is enabled. The first and fourth PMOS transistors P1 and P4 are turned off. In addition, the decoded external command signal CMDDEC of a logic high level is input so that an NMOS transistor N2 is turned on. In such a state, the latch unit 103 outputs the internal command signals CMDDEC′.

As a result, the decoded external command signal CMDDEC is latched and is output when the command strobe signal COS changes from the logic low level to the logic high level.

FIG. 6 is a diagram of a DRAM chip having a plurality of pads for receiving the command strobe signal COS.

Referring to FIG. 6, the DRAM chip includes a plurality of command pads /CASPAD, /RASPAD, /WEPAD and CKEPAD for receiving command signals /CAS, /RAS, /WE and CKE, and a command strobe pad COSPAD for receiving the command strobe signal COS transferred from the chipset. The command strobe signal COS is an echo signal of the external command signals /CAS, /RAS, /WE and CKE.

The pads /CASPAD, /RASPAD, /WEPAD, CKEPAD and COSPAD are wire-bonded to corresponding pins to receive the command strobe signal COS and the external command signals /CAS, /RAS, /WE and CKE.

Because the chipset outputting the external command signal also outputs the command strobe signal for synchronizing the external command signal through the same path, the DRAM chip can solve the skew problem that is caused between the clock signal and the external command signal due to the difference between the transfer path of the external clock signal and the transfer path of the external command signal.

The types and arrangements of the logics used in the aforementioned embodiments have been provided for the case where all the input/output signals are high active signals. Therefore, when the active polarities of the signals are changed, the logic implementations will also be modified. These implementations can be achieved in various ways and their modifications can be easily derived by those skilled in the art.

In addition, it will be apparent that the latch unit may be implemented with various logic circuits.

As described above, the DRAM receives the external command signal from the chipset in synchronization with the command strobe signal that is also transferred from the chipset.

Therefore, the external command signals transferred from the chipset can be received at high stability and high reliability, thereby improving the stability and reliability of the semiconductor memory device.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device, comprising:
a plurality of command pins for receiving a plurality of command signals from a chipset; and
a command strobe pin for receiving a command strobe signal from the chipset.

2. The semiconductor memory device as recited in claim 1, wherein the command strobe signal is an echo signal of the command signals.

3. A semiconductor memory device, comprising:
an internal command signal generator for receiving an external command signal and a command strobe signal from a chipset to generate an internal command signal by decoding the external command signal in response to the command strobe signal; and
a plurality of operation circuits for performing an internal operation of the semiconductor memory device based on the internal command signal.

4. The semiconductor memory device as recited in claim 3, wherein the internal command signal generator includes:
a plurality of command input units for receiving the external command signal from the chipset;
a command strobe signal input unit for receiving the command strobe signal from the chipset; and
a command decoding unit for decoding the external command signal to generate a decoded external command signal; and
a command latch unit for latching the decoded external command signal in response to the command strobe signal output from the command strobe signal input unit to output the internal command signal.

5. The semiconductor memory device as recited in claim 4, wherein the command strobe signal is an echo signal of the command signal.

6. The semiconductor memory device as recited in claim 4, wherein the command input unit comprises a buffer for buffering a level between the external command signal and an internal operation of the semiconductor memory device.

7. The semiconductor memory device as recited in claim 3, wherein the plurality of operation circuits includes active/read/write/precharge circuits.

8. A method for driving a semiconductor memory device, comprising:
receiving an external command signal and a command strobe signal from a chipset to generate an internal command signal in response to the command strobe signal; and
performing an internal operation of the semiconductor memory device based on the internal command signal.

9. The method as recited in claim 8, wherein the receiving the external command signal and the command strobe signal includes:
receiving the external command signal and the command strobe signal from the chipset;
decoding the external command signal to generate a decoded external command signal; and
latching the decoded external command signal in response to the command strobe signal to output the internal command signal.

10. The method as recited in claim 9, wherein the command strobe signal is an echo signal of the command signal.
